(19) United States
(12) Patent Application Publication
(10) Pub. No.: US 2017/0069568 A1
(43) Pub. Date: Mar. 9, 2017

(54) CAPACITOR FORMED IN SEMICONDUCTOR

(71) Applicant: KABUSHIKI KAISHA TOSHIBA, Tokyo (JP)

(72) Inventors: Ken INAZUMI, Oita Oita (JP); Hiroto OHNO, Oita Oita (JP); Katsumi EGASHIRA, Oita Oita (JP)

(21) Appl. No.: 15/063,129

(22) Filed: Mar. 7, 2016

Related U.S. Application Data
(60) Provisional application No. 62/215,412, filed on Sep. 8, 2015.

(51) Int. Cl. H01L 23/522; H01L 23/528

(52) U.S. Cl. CPC H01L 23/5223; H01L 23/5226; H01L 23/528

(57) ABSTRACT

According to an embodiment, a capacitor includes a first electrode, a second electrode and a first via. The first electrode is provided in a first interconnect layer. The second electrode is provided in the first interconnect layer and surrounds a periphery of the first electrode by a closed circuit. The first via is connected to the first electrode and provided to pass through the first interconnect layer.

### CROSS-REFERENCE TO RELATED APPLICATIONS

This application is based upon and claims the benefit of priority from Provisional Application No. 62/215,412, filed on Sep. 8, 2015; the entire contents of which are incorporated herein by reference.

### FIELD

Embodiment described herein relates to a capacitor formed in semiconductor.

### BACKGROUND

Various types of capacitors are used in integrated circuits. There is an interconnect capacitor in which part of a pair of interconnects are made to face each other to easily obtain capacitance. In the interconnect capacitor, when micronization advances and a high breakdown voltage process is applied, a situation may occur in which a desired capacitance is difficult to be realized while a breakdown voltage between the wirings is secured.

### BRIEF DESCRIPTION OF THE DRAWINGS

FIG. 1A is a perspective view illustrating a capacitor of a first embodiment.

FIG. 1B is a plan view illustrating the capacitor of the first embodiment.

FIG. 1C is a sectional view taken in AA of FIG. 1B.

FIG. 2 is a plan view illustrating a capacitor of a comparative example.

FIG. 3A is a plan view showing sizes of main parts of the capacitor of the first embodiment used for simulating the maximum electric field intensity.

FIG. 3B is a plan view showing sizes of main parts of the capacitor of the comparative example used for simulating the maximum electric field intensity.

FIG. 4A is a perspective view illustrating a capacitor of a second embodiment.

FIG. 4B is a sectional view taken along a plane B of FIG. 4A.

FIG. 5A is a plan view illustrating a capacitor of a third embodiment.

FIG. 5B is a sectional view taken in CC of FIG. 5A.

FIG. 6 is a plan view illustrating a capacitor of a variation of the third embodiment.

FIG. 7 is a plan view illustrating a capacitor of another variation of the third embodiment.

### DETAILED DESCRIPTION

According to an embodiment, a capacitor formed in a semiconductor includes a first electrode, a second electrode and a first via. The first electrode is provided in a first interconnect layer. The second electrode is provided in the first interconnect layer and surrounds a periphery of the first electrode by a closed circuit. The first via is connected to the first electrode and provided to pass through the first interconnect layer.

Hereinafter, embodiments will be described with reference to the drawings.

### First Embodiment

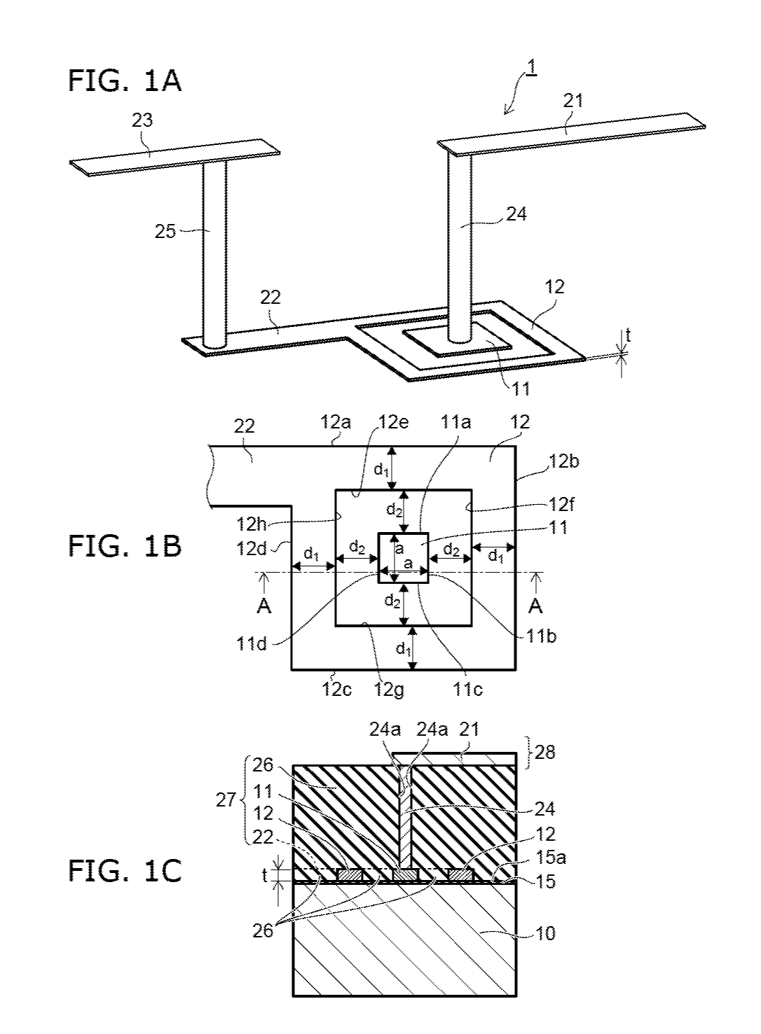

FIG. 1A is a perspective view illustrating a capacitor of a first embodiment.

FIG. 1B is a plan view illustrating the capacitor of the first embodiment.

FIG. 1C is a sectional view taken in AA of FIG. 1B.

As shown in FIG. 1A, a capacitor 1 of the embodiment includes a first electrode 11, a second electrode 12 and a via 24. The first electrode 11 and the second electrode 12 are provided on the same plane. The plane is a plane 15a of an insulating film 15 provided on a substrate 10 as described later. In the following, a description is made under the assumption that the plane 15a is a flat surface. The first electrode 11 and the second electrode 12 respectively have the same thickness t and are formed on the plane 15a. The second electrode 12 surrounds the periphery of the first electrode 11 by a closed circuit. The first via 24 is vertical to the plane 15a and extends in a direction opposite to the substrate 10. One end of the first via 24 is connected to the first electrode 11. The other end of the first via 24 is connected to a first interconnect 21. In the embodiment, the sectional shape of the first via 24 is arbitrary. The sectional shape of the first via 24 on a plane parallel to the plane 15a may be circular as in the example, or may be a shape similar to the shape of the first electrode 11 in plan view. The first electrode 11, the second electrode 12 and the first via 24 are formed of metal containing high conductivity material such as copper or aluminum.

The first electrode 11 is connected to the first interconnect 21 through the first via 24. The second electrode 12 is connected to a second interconnect 22 provided on the plane 15a. The first interconnect 21 and the second interconnect 22 are formed of metal containing high conductivity material such as copper or aluminum. That is, the capacitor 1 is connected to an external circuit through the first interconnect 21 and the second interconnect 22. Incidentally, in the capacitor 1, the second interconnect 22 may be connected to a third interconnect 23 through a second via 25 as in the example.

As shown in FIG. 1B, the first electrode 11 is a rectangle including four sides 11a to 11d in plan view. In the example, lengths “a” of the four sides 11a to 11d are equal to each other and the first electrode 11 is square in plan view.

The second electrode 12 is a rectangular frame body including four outer peripheral sides 12a to 12d and four inner peripheral sides 12e to 12h. In the example, lengths b1 of the four outer peripheral sides 12a to 12d are equal to each other, and lengths b2 of the four inner peripheral sides 12e to 12h are equal to each other. The length b1 is larger than the length b2. A width d1 of a frame of the second electrode 12 is equal to (b1−b2)/2. That is, both the outer periphery and the inner periphery of the frame body are square.

The side 11a of the first electrode 11 faces the inner peripheral side 12e of the second electrode 12 on the same plane. A shortest distance d2 between the side 11a and the side 12e is equal to (b2−a)/2. Similarly, the side 11b of the first electrode 11 faces the inner peripheral side 12f of the second electrode 12 on the same plane. A shortest distance between the side 11b and side 12f is d2. The side 11c of the first electrode 11 faces the inner peripheral side 12g of the second electrode 12. A shortest distance between the side 11c and the side 12 is d2. The side 11d of the first electrode 11 faces the inner peripheral side 12h of the second electrode 12. A shortest distance between the side 11d and the side 12h is d2. That is, the respective facing sides are provided to be parallel to each other, and are disposed so that the center of gravity (center) of the first electrode 11 in plan view coincides with the center of gravity (center) of the second electrode 12 in plan view.

As shown in FIG. 1C, the capacitor 1 of the embodiment is formed in a interconnect layer 27. The interconnect layer 27 includes the first electrode 11, the second electrode 12, the first via 24 and an insulating layer 26. The first electrode 11 and the second electrode 12 are provided on the plane 15a of the insulating film 15. The plane 15a is a plane forming a boundary between the insulating film 15 and the interconnect layer 27. The thicknesses of the first electrode 11 and the second electrode 12 are respectively t. That is, the first electrode 11 is a rectangular parallelepiped having the square section and the height t. The second electrode 12 is a tubular body having the square section and the height t, and the thickness of the tube is d2. Incidentally, although a layer under the interconnect layer 27 is the substrate 10 and the insulating layer 15 in the example, more generally, the layer may be another interconnect layer.

One end of the first via 24 is connected to the first electrode 11, and the first via 24 extends vertically toward the opposite side to the substrate 10 with respect to the plane 15a. The other end of the first via 24 extends until reaching another interconnect layer 28. The interconnect layer 28 is an upper interconnect layer of the interconnect layer 27. The other end of the first via 24 is connected to the first interconnect 21 in the interconnect layer 28.

The insulating layer 26 is provided between the first electrode 11 and the interconnect layer 28. The insulating layer 26 is provided between the second electrode 12 and the interconnect layer 28. The insulating layer 26 is provided also between the first electrode 11 and the second electrode 12. The insulating layer 26 is formed of, for example, inorganic material such as silicon oxide. The insulating layer 26 insulates between the first electrode 11 and the second electrode 12, and functions also as a dielectric of the capacitor 1.

The first via 24 and the second via 25 are respectively formed by filling via holes 24a and 25a opened in the insulating layer 26.

As described above, the capacitor 1 of the embodiment can be easily manufactured by using an existing multilayer interconnect technique.

The operation of the capacitor 1 of the embodiment will be described.

In the capacitor 1 of the embodiment, since the first electrode 11 is surrounded by the second electrode 12, the first electrode 11 and the first interconnect 21 are connected through the first via 24 passing through the insulating layer 26. Accordingly, the capacitor 1 can be freely connected to an external circuit. Incidentally, when the second electrode 12 is also connected to the second interconnect 22 through the second via 25 passing through the insulating layer 26, the capacitor 1 can be connected to an external circuit in the same interconnect layer 28.

A capacitance value of the capacitor 1 of the embodiment is determined as described below.

The capacitance value based on the first electrode 11 and the second electrode 12 is obtained in relation to the product of the lengths of the sides 11a to 11d and 12e to 12h of the facing electrodes and the thickness t. Besides, the capacitance value based on the first electrode 11 and the second electrode 12 is obtained in relation to the distances between the sides 11a to 11d and the sides 12e to 12h of the facing electrodes.

Since the first electrode 11 and the second electrode 12 are formed simultaneously with the other interconnect formed on the plane 15a, the thickness t of the electrodes and the other interconnect is the same. Accordingly, as the lengths of the sides of the facing electrodes become long, the capacitance value based on the first electrode 11 and the second electrode 12 becomes large. Besides, as the distance between the sides of the facing electrodes becomes short, the capacitance value becomes larger.

On the other hand, as the distance between the sides 11a to 11d and the sides 12e to 12h of the facing electrodes becomes short, electric field intensity becomes high. Thus, the separation distance is set with sufficient margin to prevent breakdown or deterioration in breakdown voltage from occurring according to a voltage used in a circuit.

From the above, the capacitance value based on the first electrode 11 and the second electrode 12 can be made large by increasing the length “a” of the side of the first electrode 11 and by increasing the length b2 of the side of the inner periphery of the second electrode 12. Incidentally, since the inter-electrode area relative to the first electrode 11 can be substantially increased also by extending the width d1 of the frame part of the second electrode 12, this contributes to slightly increasing the capacitance value.

An action effect of the capacitor 1 of the embodiment will be described.

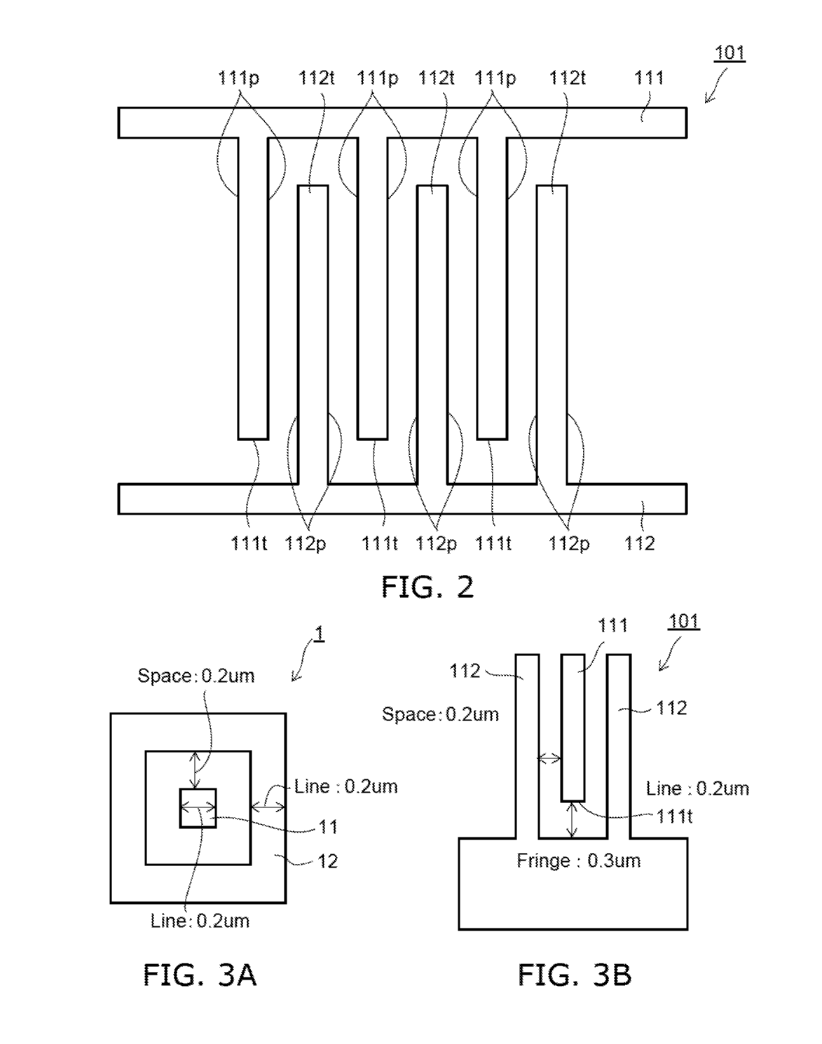

FIG. 2 is a plan view illustrating a capacitor of a comparative example.

FIG. 3A is a plan view showing sizes of main parts of the capacitor of the first embodiment used for simulating the maximum electric field intensity. FIG. 3B is a plan view showing sizes of main parts of the capacitor of the comparative example used for simulating the maximum electric field intensity.

As shown in FIG. 2, a technique is known in which a comb-shaped first electrode 111 and a comb-shaped second electrode 112 are provided, and a capacitance value is increased by increasing the length of the facing electrodes between the two electrodes.

On the other hand, in the case of a capacitor 101 using the comb-shaped electrodes 111 and 112, since the shape of the two facing electrodes has a portion protruding as compared with the other portion, electric field concentration occurs at the portion, and breakdown voltage failure may occur. In the example, the protruding portion is tip portions 111t and 112t of the respective comb-shaped electrodes 111 and 112. Although electric field is uniformly distributed in parallel-disposed portions 111p and 112p on the side of long sides, electric field distribution becomes irregular in the tip parts 111t and 112t, and the electric field concentration can occur.

With respect to the capacitor 1 of the embodiment and the capacitor 101 of the comparative example, the maximum electric field intensity obtained when the same voltage is applied between the electrodes can be obtained by simulation. In FIG. 3A, the left figure represents the capacitor 1 of the embodiment. The length of the side of the first electrode 11 is set to 0.2 μm. The frame width d1 of the second electrode 12 is set to 0.2 μm. All of the shortest separation distances between the sides 11a to 11d of the first electrode 11 and the facing sides 12e to 12h are 0.2 μm.

The figure shown in FIG. 3B represents the capacitor 101 of the comparative example. The size of the capacitor 101 of the comparative example is set so as to have the same capacitance value as that of the capacitor 1 of the embodiment. The separation distance between the facing long sides of the first electrode 111 and the second electrode 112 is set to 0.2 μm. The shortest separation distance between the tip part 111t of the first electrode 111 and the second electrode 112 is set to 0.3 μm. Incidentally, the reason why the shortest separation distance between the tip part 111t of the first electrode 111 and the second electrode 112 is longer than the separation distance between the other portions is that electric field is expected to be concentrated in the portion, and therefore, the separation distance is set to be long in advance.

When a voltage of 40V is applied between the electrodes of the capacitor 1 of the embodiment and between the electrodes of the capacitor 101 of the comparative example, the maximum electric field intensity is 2.2 MV/cm in the capacitor 1 of the embodiment. On the other hand, the maximum electric field intensity is 2.37 MV/cm in the capacitor 101 of the comparative example. That is, when the same voltage is applied, the electric field intensity is reduced by about 7% in the capacitor 1 of the embodiment as compared with the capacitor 101 of the comparative example, and the electric field concentration is relaxed. As stated above, since the separation distance between the tip part 111t and the second electrode 112 is long in the capacitor 101 of the comparative example, if the separation distance between the tip part 111t of the first electrode 111 and the second electrode 112 is made short, a further difference appears to occur.

In the capacitor 1 of the embodiment, the square first electrode 11 is disposed to be surrounded by the second electrode 12 including the square inner periphery similar to the first electrode 11, and the facing electrodes are disposed to be almost in parallel to each other. Thus, the shortest distance between the facing electrodes becomes almost the same for the respective sides 11a to 11d and 12e to 12h of the electrodes. Thus, the electric field distribution becomes almost the same for the respective sides, and the non-uniformity of the electric field intensity is relaxed. In general, an electric field concentration is liable to occur at a corner part of an electrode. However, in the capacitor 1 of the embodiment, since the separation distance between the corner part of the first electrode 11 and the corner part of the inner periphery of the second electrode 12 is longer than the distance between the facing electrodes disposed in parallel, the electric field intensity is reduced. Thus, in the capacitor 1, the limit value of the electric field intensity is improved.

The number of the corner parts of each of the electrodes is four in the capacitor 1 of the embodiment, while the number of the corner parts of the electrode is two in the capacitor 101 of the comparative example. Thus, in the capacitor 1 of the embodiment, since sharing is performed by the corner parts the number of which is larger than that of the capacitor 101 of the comparative example, the electric field concentration can be more relaxed. Accordingly, in the capacitor 1 of the embodiment, the maximum electric field intensity can be relaxed.

Further, in the capacitor 1 of the embodiment, since the first electrode 11 surrounded the periphery can be connected by using the first via 24, a desired capacitance value can be obtained without increasing the installation area of the capacitor 1.

### Second Embodiment

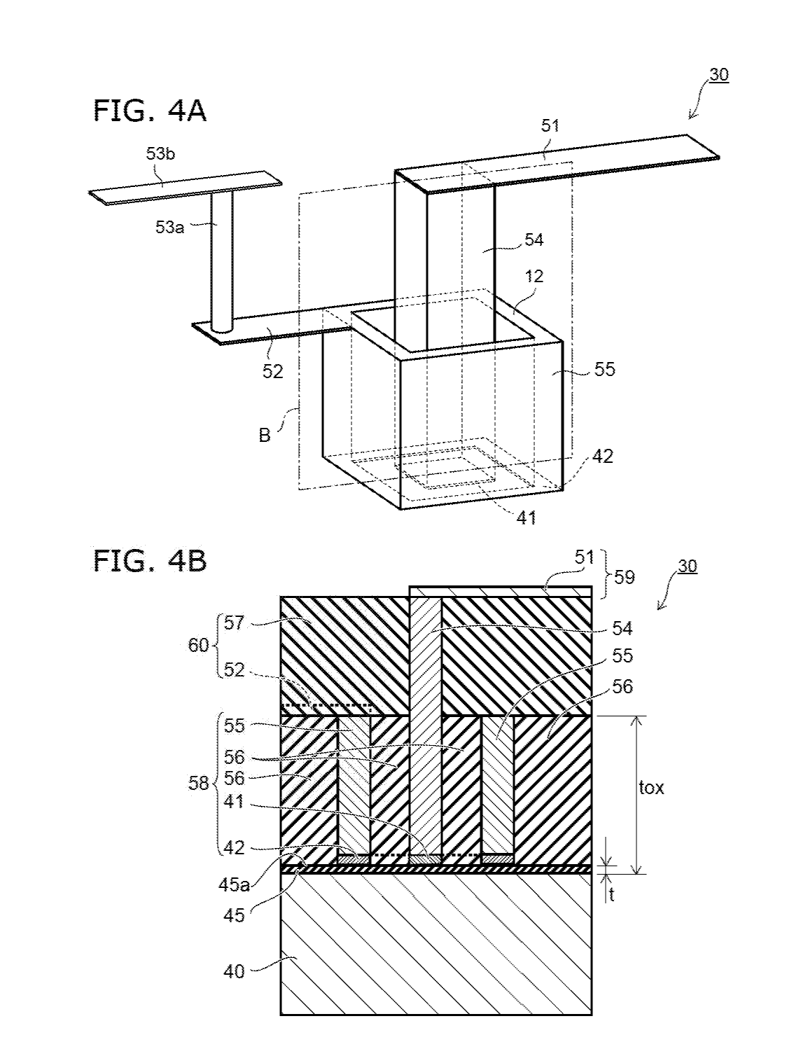

FIG. 4A is a perspective view illustrating a capacitor of a second embodiment.

FIG. 4B is a sectional view taken along a plane B of FIG. 4A.

In the capacitor of the above embodiment, the capacitance value is set by the lengths of two facing electrodes provided on the same plane. The capacitance value can be further increased by extending the two electrodes in the thickness direction.

As shown in FIG. 4A, a capacitor 30 of the embodiment includes a first electrode 41, a second electrode 42, a first via 54 and a second via 55. The shapes of the first electrode 41 and the second electrode 42 in plan view are similar to those of the first embodiment. That is, the first electrode 41 is square, and the second electrode 42 is a square frame body. The second electrode 42 surrounds the first electrode by a closed circuit. The first electrode 41 and the second electrode 42 are provided on the same plane. The same plane is a plane 45a of an insulating film 45 formed on a substrate 40 and the plane 45a is on the opposite side to the substrate 40 (FIG. 4B).

One end of the first via 54 is connected to the first electrode 41. The other end of the first via 54 is connected to a first interconnect 51. The sectional shape of the first via 54 on a plane parallel to the plane 45a almost coincides with the shape of the first electrode 41 in plan view. The first via 54 is integrated with the first electrode 41 and forms one electrode of the capacitor 30. That is, the first via 54 has a rectangular column shape vertical to the plane 45a and extending toward an opposite side to the substrate 40.

One end of the second via 55 is connected to the second electrode 42. The other end of the second via 55 is connected to a second interconnect 52. The sectional shape of the second via 55 taken along a plane parallel to the plane 45a almost coincides with the shape of the second electrode 42 in plan view. The second via 55 is integrated with the second electrode 42 and forms the other electrode of the capacitor 30. The second via 55 has a square tubular shape vertical to the plane 45a and extending toward an opposite side to the substrate 40.

Incidentally, the second interconnect 52 may be connected to a third interconnect 53b through a third via 53a as in the example.

As shown in FIG. 4B, the capacitor 30 of the embodiment is formed in a interconnect layer 58. The interconnect layer 58 includes the first electrode 41, the second electrode 42, part of the first via 54, the second via 55 and an insulating layer 56. In the capacitor 30, the first electrode 41 is connected to the first interconnect 51 in a interconnect layer 59. The interconnect layer 59 includes the first interconnect 51. In the capacitor 30, the second electrode 42 is connected to the second interconnect 52 in a interconnect layer 60. The interconnect layer 60 includes the second interconnect 52 and an insulating layer 57. The interconnect layer 60 is provided between the lower interconnect layer 58 and the upper interconnect layer 59.

The first electrode 41 and the second electrode 42 are provided on the plane 45a.

The first electrode 41 is connected through the first via 54 to the first interconnect 51 provided in the interconnect layer 59 above the interconnect layer 58 including the first electrode 41 and the second electrode 42. The first via 54 is provided to pass through the interconnect layer 58 and the interconnect layer 60. More specifically, the via 54 is provided to fill a via hole passing through the insulating layer 56 of the interconnect layer 58 and the insulating layer 57 of the interconnect layer 60.

The second electrode 42 is connected through the second via 55 to the second interconnect 52 in the interconnect layer 60 provided between the interconnect layer 58 and the upper interconnect layer 59. The second via 55 is provided to pass through the interconnect layer 58. The via 55 is provided to fill a via hole passing through the insulating layer 56 of the interconnect layer 58.

That is, the first electrode 41 is connected through the first via 54 to the first interconnect 51 in the interconnect layer 59 above the second interconnect 52 connected to the second electrode 42. Besides, the second electrode 42 is connected to the second interconnect 52 through the second via 55.

The insulating layer 56 is provided between the first electrode 41 and the interconnect layer 60. The insulating layer 56 is provided between the second electrode 42 and the interconnect layer 60. The insulating layer 56 is provided also between the first electrode 41 and the second electrode 42. In the interconnect layer 58, the insulating layer 56 is provided also between the first via 54 and the second via 55. That is, the insulating layer 56 ensures insulation between the first electrode 41 and the second electrode 42 and also functions as a dielectric layer between the electrodes. Simultaneously, the insulating layer 56 ensures insulation between the first via 54 and the second via 55 and functions as a dielectric layer between the vias.

In the interconnect layer 60, the insulating layer 57 is provided between the interconnect layer 58 and the interconnect layer 59 and also on the upper surface and the side surface of the second interconnect 52.

In the interconnect layer 58, the first via 54 connected to the first electrode 41 and the second via 55 connected to the second electrode 42 are upwardly provided in parallel to each other and vertically to a plane including the plane 45a. That is, facing electrodes are formed of the outer peripheral surface of the rectangular column-shaped via 54 and the inner wall of the tube-shaped via 55 containing the via 54 therein, and the facing electrodes constitute a part of the capacitor 30.

As stated above, the capacitor 30 of the embodiment can be easily manufactured by using an existing multi-layer interconnect technique similarly to the other embodiment.

An operation of the capacitor 30 of the embodiment will be described.

In the capacitor 30 of the embodiment, since the first electrode 41 is surrounded by the second electrode 42, the first electrode 41 and the first interconnect 51 are connected through the first via 54 passing through the insulating layers 56 and 57. Besides, the second electrode 42 and the second interconnect 52 are connected through the second via 55 passing through the insulating layer 56. Accordingly, the capacitor 30 can be freely connected to an external circuit. Incidentally, when the second electrode 42 is also connected to the third interconnect 53b through the third via 53a passing through the insulating layer 57, the capacitor 30 can be connected to an external circuit in the same interconnect layer 59.

A capacitance value of the capacitor 30 of the embodiment is determined as described below.

In the capacitor 30 of the embodiment, the facing electrodes are formed of the surface of the rectangular column-shaped via 54 and the inner wall of the tube-shaped via 55 containing the via 54 therein. When a thickness of the interconnect layer 58 is tox, the capacitor 30 of the embodiment has the capacitance value proportional to tox. In the capacitor 1 of the first embodiment, the area of the facing electrodes is obtained in relation to the thickness t of the first electrode and the second electrode. On the other hand, in the capacitor 30 of the embodiment, the area of the facing electrodes is obtained in relation to tox sufficiently larger than t. Accordingly, in the capacitor 30 of the embodiment, the capacitance value tox/t times larger than that of the capacitor 1 of the first embodiment can be obtained in the same occupied area on the plane 45a.

An action effect of the capacitor 30 of the embodiment will be described.

The capacitor 30 of the embodiment includes the via 54 which is the columnar body having the same sectional shape as that of the first electrode 41 and the via 55 which is the tubular body having the same sectional shape as that of the second electrode 42. Thus, the facing area of the electrodes increases, and the large capacitance value can be obtained.

The capacitance value of the capacitor 30 of the embodiment can be made a large value proportional to the thickness tox of the insulating layer 56 in which the surface of the first via 54 and the inner wall surface of the second via 55 face each other.

### Third Embodiment

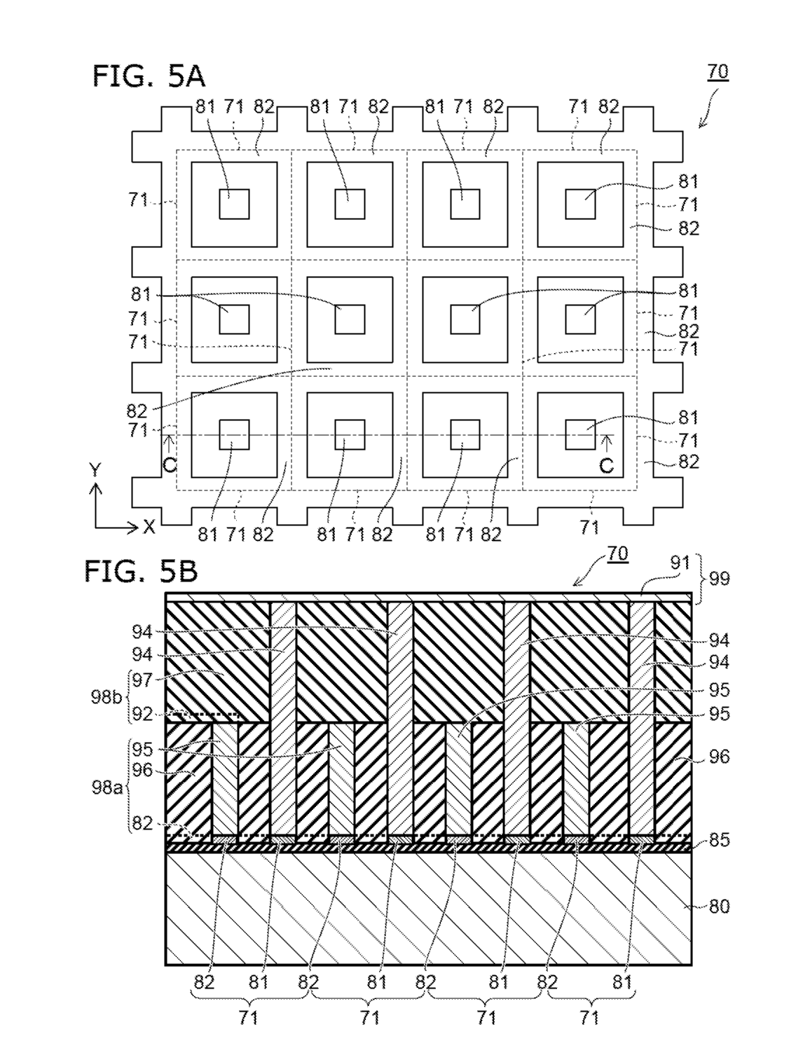

FIG. 5A is a plan view illustrating a capacitor of a third embodiment.

FIG. 5B is a sectional view taken in CC of FIG. 5A.

As described above, a first electrode can be connected through a via to a interconnect layer above a interconnect layer in which the first electrode is provided. Thus, when plural first electrodes are provided, each of the electrodes is extracted to another interconnect layer and can be connected. Hereby, the first electrodes and vias can be made one electrode. Besides, also with respect to a second electrode, second electrodes are formed so as to respectively surround the plural first electrodes and the adjacent second electrodes are connected, so that the other electrode can be formed.

As shown in FIG. 5A, a capacitor 70 of the embodiment includes plural unit capacitors 71. Each of the plural unit capacitors 71 includes a first electrode 81 and a second electrode 82. The second electrode 82 surrounds the first electrode 81 by a closed circuit. The shape and the configuration of the first electrode 81 and the second electrode 82 are the same as those of the foregoing other embodiments.

In the capacitor 70 of the embodiment, the unit capacitors 71 are arranged in a lattice shape on the same plane. In the example, the second electrode 82 is connected to the adjacent second electrodes 82 and is integrated.

In the example, the center of gravity (center) of the unit capacitor 71 is disposed along an X-axis parallel to one side of the unit capacitor 71, and the center of gravity (center) of the unit capacitor 71 is disposed along a Y-axis perpendicular to the X-axis. Incidentally, the disposition on the XY plane is not limited to such lattice shape, and for example, a staggered disposition may be adopted in which the gravity center positions of the unit capacitors disposed alternately in the Y-axis direction are shifted in the X-axis direction.

As shown in FIG. 5B, the capacitor 70 of the embodiment is formed in a interconnect layer 98a. The interconnect layer 98a includes the first electrode 81, the second electrode 82, part of a first via 94, a second via 95 and an insulating layer 96. In the capacitor 70, the first electrode 81 is connected to a first interconnect 91 in a interconnect layer 99. The interconnect layer 99 includes the first interconnect 91. In the capacitor 70, the second electrode 82 is connected to a second interconnect 92 in a interconnect layer 98b. The interconnect layer 98b includes the second interconnect 92 and the insulating layer 97. The interconnect layer 98b is provided between the lower interconnect layer 98a and the upper interconnect layer 99.

The first via 94 passes through the interconnect layers 98a and 98b and reaches the interconnect layer 99. One end of the first via 94 is connected to the first electrode 81, and the other end is connected to the first interconnect 91 in the upper interconnect layer 98. In the interconnect layer 98a, the plural respective first electrodes 81 are connected through the first interconnect 91 and form one electrode. The second via 95 passes through the interconnect layer 98a and reaches the interconnect layer 98b. One end of the second via 95 is connected to the second electrode 82, and the other end is connected to the second interconnect 92 in the interconnect layer 98b above the interconnect layer 98a. The second via 95 and the second interconnect 92 form the other electrode of the capacitor 70 in the interconnect layer 98b.

The insulating layer 96 provided between the respective electrodes and between the vias insulates between the respective electrodes and between the vias, and functions also as a dielectric layer of the capacitor 70.

An action effect of the capacitor 70 of the embodiment will be described.

The capacitor 70 of the embodiment includes the plural unit capacitors 71, and the first electrodes 81 and the second electrodes 82 of the plural respective unit capacitors 71 are connected to each other. That is, the capacitor 70 is configured of the plural parallel-connected unit capacitors 71. Accordingly, the capacitance value of the capacitor 70 can be increased in accordance with the number of the unit capacitors 71 which are arranged in a lattice shape and are parallel connected. For example, when the n unit capacitors 71 are arranged in the X-axis direction and the m unit capacitors 71 are arranged in the Y-axis direction, the capacitance value of the capacitor 70 is n x m times larger than the capacitance value of the unit capacitor 71.

### Variations of the Third Embodiment

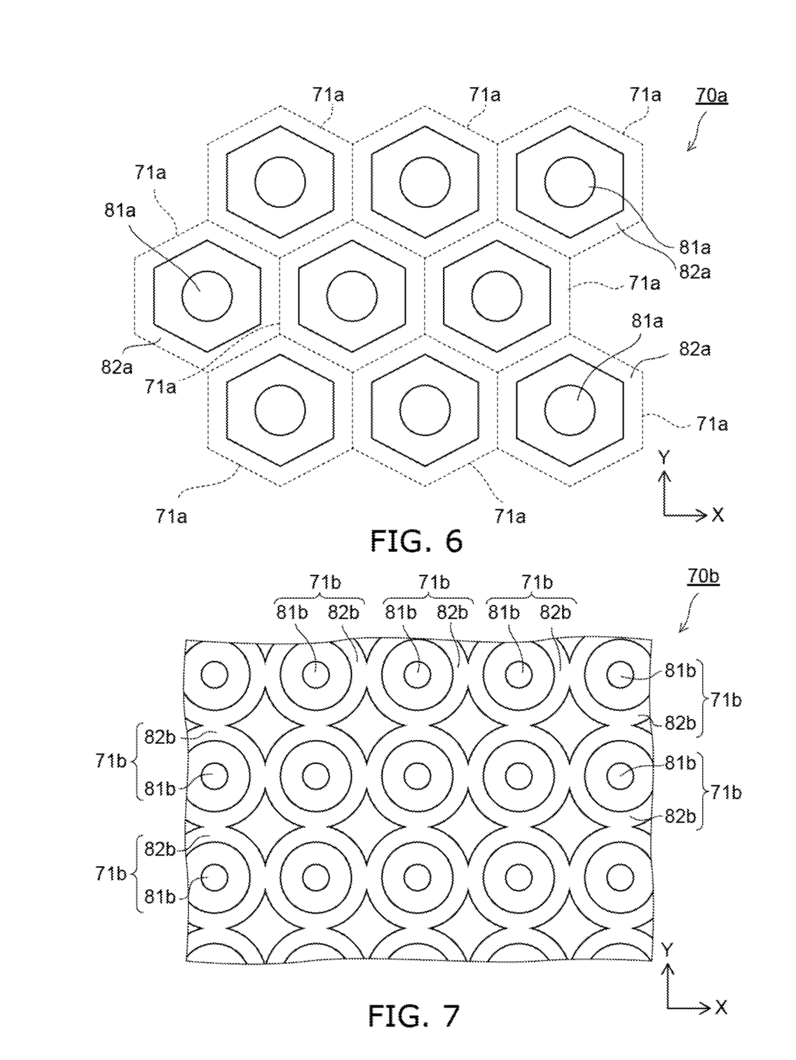

FIG. 6 is a plan view illustrating a capacitor of a variation of the third embodiment.

FIG. 7 is a plan view illustrating a capacitor of another variation of the third embodiment.

As described above, in the capacitor, the capacitance value can be increased by increasing the area of the facing electrodes. The lengths of the facing sides of the first electrode and the second electrode are required to be increased in order to increase the facing area of the facing electrodes. On the other hand, when the length of the side of the electrode is increased, the outer peripheral size of the electrode is increased, and the size of the electrode in plan view is required to be increased. In general, since a region and area in which a capacitor can be disposed are often limited in a region on an integrated circuit, it is preferable that a large capacitor can be disposed in the limited region and area. That is, it is desired to decrease the occupied area of the capacitor in the integrated circuit.

Besides, as described above, since an electric field concentration is liable to occur at the corner part of an electrode, the electric field concentration can be relaxed by increasing the number of corner parts. Besides, since the angle of the corner part becomes an obtuse angle by increasing the number of corner parts of the electrode, the electric field concentration can be made hard to occur.

As shown in FIG. 6, in a capacitor 70a of the variation, the shape of each of second electrodes 82a of plural unit capacitors 71a in plan view forms a regular hexagonal frame body. Sides of outer peripheries of the second electrodes 82 are connected to each other, so that the respective unit capacitors 71a are closely arranged. Although the shape of a first electrode 81 in plan view is circular in the example, the shape may be a hexagonal shape similar to the outer peripheral or inner peripheral shape of the second electrode 82.

In the capacitor 70a of the variation, the outer peripheral and inner peripheral shapes of the second electrode 82a are made regular hexagonal, so that the length of the inner periphery per unit area can be made longer than that of a case of a square. Accordingly, the capacitance value can be increased. The shape of the first electrode 81 may be circular as in the variation, or may be a regular hexagonal shape similar to the second electrode 82.

In the variation of FIG. 7, a capacitor 70b includes a plural of capacitor elements 71b, a first electrode 81b and a second electrode 82b are concentrically provided. The center of a circle of the first electrode 81b and the centers of an outer circumference and an inner circumference of the second electrode 82b are disposed to almost coincide with each other. When the shape is set and disposed in this way, the shortest separation distance between the facing sides can be made identical at any point, and the electric field distribution at voltage application can be made circumferentially uniform. Thus, since the electric field concentration does not occur between any electrodes, the inter-electrode distance can be shortened and the occupied area can be reduced.

What is claimed is:

1. A capacitor formed in a semiconductor comprising:
a first electrode provided in a first interconnect layer;
a second electrode provided in the first interconnect layer and surrounding a periphery of the first electrode by a closed circuit; and
a first via connected to the first electrode and provided to pass through the first interconnect layer.

2. The capacitor according to claim 1, further comprising:
a second interconnect layer stacked on the first interconnect layer; and
a second via connected to the second electrode and provided to pass through the first interconnect layer, wherein
the first via is provided to pass through the first interconnect layer and the second interconnect layer.

3. The capacitor according to claim 2, wherein the first interconnect layer includes an insulating layer.

4. The capacitor according to claim 3, wherein the first via is a columnar body having the first electrode at one end.

5. The capacitor according to claim 4, wherein the second via is a tubular body having the second electrode at one end.

6. The capacitor according to claim 5, wherein the first electrode has a square shape, and a shape of an inner periphery of the second electrode is a square shape similar to the first electrode and includes sides parallel to respective sides of the square.

7. The capacitor according to claim 5, wherein the first electrode is circular.

8. The capacitor according to claim 7, wherein a shape of an inner periphery of the second electrode is a regular hexagonal shape.

9. The capacitor according to claim 7, wherein a shape of an inner periphery of the second electrode is a circular shape similar to the first electrode.

10. The capacitor according to claim 9, wherein on the first interconnect layer, a center of the first electrode coincides with a center of the shape of the inner periphery of the second electrode.

11. A capacitor formed in a semiconductor comprising:
a plurality of first electrodes provided in a first interconnect layer;
a second electrode provided in the first interconnect layer and surrounding each of peripheries of the plurality of first electrodes by a closed circuit;
an insulating layer provided between the first electrode and the second electrode; and
a plurality of first vias respectively connected to the plurality of first electrodes and passing through the first interconnect layer.

12. The capacitor according to claim 11, further comprising:
a second interconnect layer stacked on the first interconnect layer; and
a second via connected to the second electrode and provided to pass through the first interconnect layer and the second interconnect layer.

13. The capacitor according to claim 12, wherein
the plurality of first vias are columnar bodies respectively having the plurality of first electrodes at one ends, and
the second via is a tubular body having the second electrode at one end.
